(19) United States
(12) Patent Application Publication
(10) Pub. No.: US 2013/0044120 A1
(43) Pub. Date: Feb. 21, 2013

(54) THERMAL COLOR SHIFT REDUCTION IN LCDS

(71) Applicants: Zhibing Ge, Sunnyvale, CA (US); Meizi Jiao, Cupertino, CA (US); Jun Qi, Cupertino, CA (US); Cheng Chen, Cupertino, CA (US); Young Bae Park, San Jose, CA (US); Shih Chang Chang, Cupertino, CA (US); Victor Hao-En Yin, Cupertino, CA (US); John Z. Zhong, Cupertino, CA (US)

(72) Inventors: Zhibing Ge, Sunnyvale, CA (US); Meizi Jiao, Cupertino, CA (US); Jun Qi, Cupertino, CA (US); Cheng Chen, Cupertino, CA (US); Young Bae Park, San Jose, CA (US); Shih Chang Chang, Cupertino, CA (US); Victor Hao-En Yin, Cupertino, CA (US); John Z. Zhong, Cupertino, CA (US)

(73) Assignee: APPLE INC., Cupertino, CA (US)

(21) Appl. No.: 13/213,805

(22) Filed: Aug. 19, 2011

(51) Int. Cl. G09G 5/02; H01L 33/08; G02F 1/1335

(52) U.S. Cl. 345/589; 349/110; 438/30

(57) ABSTRACT

Systems, methods, and devices are provided for an electronic display with thermally compensated pixels. Such an electronic display may have an array of pixels, at least some of which may be thermally compensated pixels that exhibit reduced color shift over a 20° C. change in temperature. These thermally compensated pixels may have numbers of pixel electrode fingers, pixel electrode widths and spacings, cell gap depths, and/or pixel edge distances that cause the array of pixels to exhibit a reduced color shift than otherwise (e.g., a color shift of less than delta u′v′ of about 0.0092 from a starting white point) when the temperature of the electronic display changes from about 30° C. to about 50° C.

### BACKGROUND

The present disclosure relates generally to liquid crystal displays (LCDs) and, more particularly, to LCDs with thermally compensated pixels to reduce thermal color shift.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Handheld devices, computers, televisions, and numerous other electronic devices often use flat panel displays known as liquid crystal displays (LCDs). LCDs employ a layer of a liquid crystal material that changes orientation to permit varying amounts of light to pass in response to an electric field applied to it. To produce images of a variety of colors, an LCD may employ a variety of colors of picture elements (pixels) of certain discrete colors. For example, many LCDs employ groups of red pixels, green pixels, and blue pixels, which collectively can produce virtually any color. By varying the amount of red, green, and blue light each group of pixels emits, images can be displayed on the LCD.

The various electronic devices that employ LCDs may generate heat, causing the temperature of their respective LCDs to change. As the temperature at an LCD change, the pixels of the LCD may shift in color. Thus, an image displayed on the LCD when an electronic device is operating at one temperature may look different than the same image displayed on the LCD at a different temperature. Because different components of an electronic device may generate heat at different locations behind the LCD, some parts of the LCD to be at a very different temperature than others at any given time. Thus, the same color image data may look different at different locations of the LCD or at different times, potentially distorting the color of the image.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Embodiments of the present disclosure relate to electronic displays having an array of pixels, at least some of which may be thermally compensated pixels that exhibit reduced color shift over a 20° C. shift. These thermally compensated pixels may have numbers of pixel electrode fingers, pixel electrode widths and spacings, cell gap depths, and/or pixel edge distances that cause the array of pixels to exhibit a reduced color shift than otherwise (e.g., a color shift of less than delta u′v′ of about 0.0092 from a starting white point) when the temperature of the electronic display changes from about 20° C. from room temperature.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings in which:

FIG. 1 is a block diagram of an electronic device that employs a display with thermally compensated pixels, in accordance with an embodiment;

FIG. 2 is a perspective view of an embodiment of the electronic device of FIG. 1 in the form of a notebook computer, in accordance with an embodiment;

FIG. 3 is a front view of an embodiment of the electronic device of FIG. 1 in the form of a handheld device, in accordance with an embodiment;

FIG. 4 is a schematic exploded view of a thermally compensated pixel of an electronic display, in accordance with an embodiment;

FIG. 5 is a circuit diagram representing circuitry that may be found in an electronic display, in accordance with an embodiment;

FIG. 6 is a schematic diagram of an array of pixels of an electronic display, in accordance with an embodiment;

FIG. 7 is a schematic cross-sectional view of three thermally compensated pixels of an electronic display, in accordance with an embodiment;

FIG. 8 is a bar graph illustrating display thermal color shift from 30° C. to 50° C. at variable cell gap depths, in accordance with an embodiment;

FIGS. 9-11 are plots illustrating changes in transmittance for red, green, and blue pixels, respectively, between 30° C. to 50° C., in accordance with embodiments;

FIGS. 12 and 13 are schematic representations of liquid crystal director orientation using pixel electrodes with four and five fingers, respectively, in accordance with embodiments;

FIGS. 14 and 15 are plots representing blue pixel transmittance from 30° C. to 50° C. using five pixel electrode fingers and cell gap depths of 3.4 μm and 3.2 μm, respectively;

FIG. 16 is a bar graph illustrating display thermal color shift from 30° C. to 50° C. at a cell gap depth of 3.4 μm and different numbers and proportions of pixel electrode fingers, in accordance with an embodiment;

FIG. 17 is a bar graph illustrating display thermal color shift from 30° C. to 50° C. using various numbers of pixel electrode fingers and cell gap depths that vary according to pixel color, in accordance with an embodiment;

FIGS. 18-20 are plots comparing pixel electrode voltage to pixel transmittance for various thermally compensated pixel configurations, in accordance with embodiments;

FIG. 21 is a schematic cross-sectional view of a green, blue, and red pixel in which a black mask material edge is closer to the pixel electrode of the blue pixel than the pixel electrodes of the red or green pixels, in accordance with an embodiment;

FIG. 22 is a bar plot of display transmittance at different cellgaps in red, green and blue pixels when using a negative dielectric anisotropy liquid crystal material, in accordance with an embodiment;

FIG. 23 is a plot showing color shift at a 20° C. temperature change for different cellgaps in red, green and blue pixels when using a negative dielectric anisotropy liquid crystal material, in accordance with an embodiment;

FIG. 24 is a schematic diagram illustrating a manner of achieving different liquid crystal cell gaps in pixels of a display, in accordance with an embodiment;

FIG. 25 is a flowchart describing a method for operating an electronic display with thermally compensated pixels, in accordance with an embodiment; and

FIG. 26 is a flowchart describing a method for manufacturing an electronic display with thermally compensated pixels, in accordance with an embodiment.

### DETAILED DESCRIPTION

One or more specific embodiments of the present disclosure will be described below. These described embodiments are only examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but may nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

To reduce the amount of thermal color shift that could occur in a liquid crystal display (LCD) over a range of normal operating temperatures, embodiments of the present disclosure provide various electronic display configurations having thermally compensated pixels. These thermally compensated pixels may exhibit less thermal color shift than conventional LCDs by having particular numbers of pixel electrode fingers, pixel electrode widths and/or spacings, cell gap depths, and/or distances from a pixel edge delineated by a black mask material and a pixel electrode. Indeed, the configuration of pixels of one color may vary from pixels of another color to achieve thermally compensated pixels that exhibit a further reduced thermal color shift. The present disclosure will thus describe a variety of configurations of thermally compensated pixels.

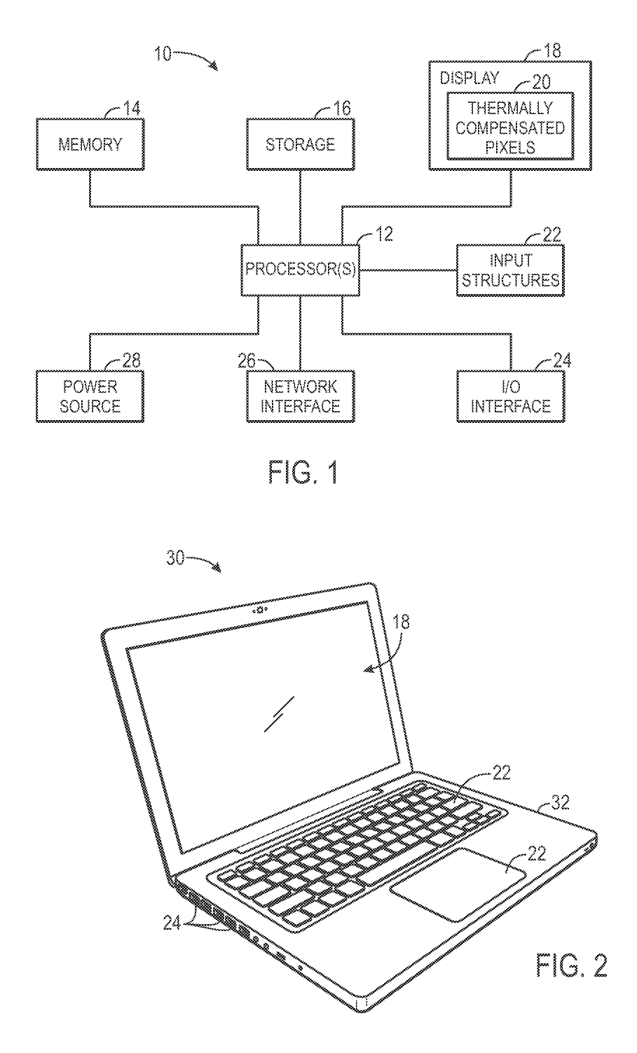

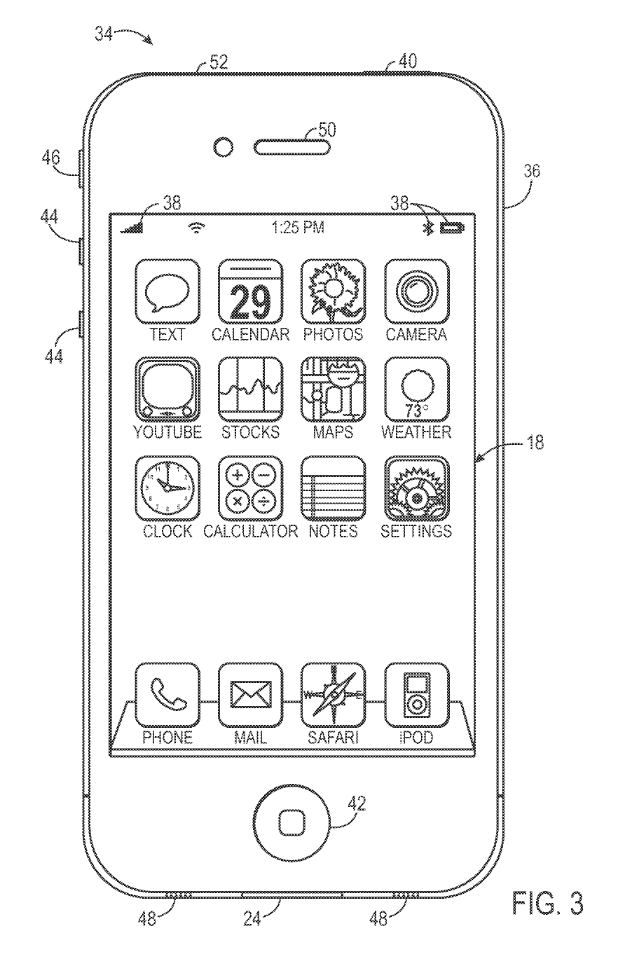

With the foregoing in mind, a general description of suitable electronic devices that may employ electronic displays having thermally compensated pixels with reduced thermal color shift will be provided below. In particular, FIG. 1 is a block diagram depicting various components that may be present in an electronic device suitable for use with such a display. FIGS. 2 and 3 respectively illustrate perspective and front views of suitable electronic device, which may be, as illustrated, a notebook computer or a handheld electronic device.

Turning first to FIG. 1, an electronic device 10 according to an embodiment of the present disclosure may include, among other things, one or more processor(s) 12, memory 14, nonvolatile storage 16, a display 18 having thermally compensated pixels 20, input structures 22, an input/output (I/O) interface 24, network interfaces 26, and a power source 28. The various functional blocks shown in FIG. 1 may include hardware elements (including circuitry), software elements (including computer code stored on a computer-readable medium) or a combination of both hardware and software elements. It should be noted that FIG. 1 is merely one example of a particular implementation and is intended to illustrate the types of components that may be present in electronic device 10.

By way of example, the electronic device 10 may represent a block diagram of the notebook computer depicted in FIG. 2, the handheld device depicted in FIG. 3, or similar devices. It should be noted that the processor(s) 12 and/or other data processing circuitry may be generally referred to herein as “data processing circuitry.” Such data processing circuitry may be embodied wholly or in part as software, firmware, hardware, or any combination thereof. Furthermore, the data processing circuitry may be a single contained processing module or may be incorporated wholly or partially within any of the other elements within the electronic device 10.

In the electronic device 10 of FIG. 1, the processor(s) 12 and/or other data processing circuitry may be operably coupled with the memory 14 and the nonvolatile memory 16 to execute instructions to carry out, among other things, certain techniques disclosed herein. These programs or instructions executed by the processor(s) 12 may be stored in any suitable article of manufacture that includes one or more tangible, computer-readable media at least collectively storing the instructions or routines, such as the memory 14 and/or the nonvolatile storage 16. The memory 14 and the nonvolatile storage 16 may represent, for example, random-access memory, read-only memory, rewritable flash memory, hard drives, and optical discs. Also, programs (e.g., an operating system) encoded on such a computer program product may also include instructions that may be executed by the processor(s) 12 to enable other functions of the electronic device 10.

The display 18 may be a touch-screen liquid crystal display (LCD), for example, which may enable users to interact with a user interface of the electronic device 10. In some embodiments, the display 18 may be a MultiTouch™ display that can detect multiple touches at once. The display 18 may be capable of operating over a range of temperatures with relatively little thermal color shift, due in large part to the thermally compensated pixels 20. The thermally compensated pixels 20 may have a thermal color shift of u′v′ of less than approximately 0.0092 in CIE 1976 color space from some starting white point when temperature changes from approximately 30° C. to 50° C., when the white point of the display 18 is designed at D65 at 30° C. Thus, despite variations in temperature of the display 18 over time or at different locations of the display 18, the colors produced by the display may remain relatively constant.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interfaces 26. The network interfaces 26 may include, for example, interfaces for a personal area network (PAN), such as a Bluetooth network, for a local area network (LAN), such as an 802.11x Wi-Fi network, and/or for a wide area network (WAN), such as a 3G or 4G cellular network. The power source 28 of the electronic device 10 may be any suitable source of power, such as a rechargeable lithium polymer (Li-poly) battery and/or an alternating current (AC) power converter.

The electronic device 10 may take the form of a computer or other type of electronic device. Such computers may include computers that are generally portable (such as laptop, notebook, and tablet computers) as well as computers that are generally used in one place (such as conventional desktop computers, workstations and/or servers). In certain embodiments, the electronic device 10 in the form of a computer may be a model of a MacBook®, MacBook® Pro, MacBook Air®, iMac®, Mac® mini, or Mac Pro® available from Apple Inc. By way of example, the electronic device 10, taking the form of a notebook computer 30, is illustrated in FIG. 2 in accordance with one embodiment of the present disclosure. The depicted computer 30 may include a housing 32, a display 18, input structures 22, and ports of an I/O interface 24. In one embodiment, the input structures 22 (such as a keyboard and/or touchpad) may be used to interact with the computer 30, such as to start, control, or operate a GUI or applications running on computer 30. For example, a keyboard and/or touchpad may allow a user to navigate a user interface or application interface displayed on display 18.

The display 18 of the computer 30 may be relatively hotter in some locations than others. Indeed, parts of the display 18 nearer to the data processing circuitry of the computer 30 may at times be, for example, 20° C. warmer than those parts of the display 18 furthest from the data processing circuitry of the computer 30. Despite these temperature variations, the thermally compensated pixels 20 may reduce the amount of color shift that would otherwise occur due to such temperature variations.

FIG. 3 depicts a front view of a handheld device 34, which represents one embodiment of the electronic device 10. The handheld device 34 may represent, for example, a portable phone, a media player, a personal data organizer, a handheld game platform, or any combination of such devices. By way of example, the handheld device 34 may be a model of an iPod® or iPhone® available from Apple Inc. of Cupertino, Calif. In other embodiments, the handheld device 34 may be a tablet-sized embodiment of the electronic device 10, which may be, for example, a model of an iPad® available from Apple Inc.

The handheld device 34 may include an enclosure 36 to protect interior components from physical damage and to shield them from electromagnetic interference. The enclosure 36 may surround the display 18, which may display indicator icons 38. The indicator icons 38 may indicate, among other things, a cellular signal strength, Bluetooth connection, and/or battery life. The I/O interfaces 24 may open through the enclosure 36 and may include, for example, a proprietary I/O port from Apple Inc. to connect to external devices.

User input structures 40, 42, 44, and 46, in combination with the display 18, may allow a user to control the handheld device 34. For example, the input structure 40 may activate or deactivate the handheld device 34, the input structure 42 may navigate user interface 20 to a home screen, a user-configurable application screen, and/or activate a voice-recognition feature of the handheld device 34, the input structures 44 may provide volume control, and the input structure 46 may toggle between vibrate and ring modes. A microphone 48 may obtain a user's voice for various voice-related features, and a speaker 50 may enable audio playback and/or certain phone capabilities. A headphone input 52 may provide a connection to external speakers and/or headphones.

Like the display 18 of the computer 30, various locations of the display 18 of the handheld device 34 also may be relatively hotter than others. For example, certain components of the handheld device 34 may be arranged beneath the display 18, generating discrete locations of heat. Thus, some parts of the display 18 may reach, for example, 20° C. warmer than parts of the display 18 not set out before heat-generating components. Despite these temperature variations, the thermally compensated pixels 20 may reduce the amount of color shift that would otherwise occur due to the temperature variations.

As noted above, the display 18 may include an array or matrix of picture elements (pixels). By varying an electric field associated with each pixel, the display 18 may control the orientation of liquid crystal disposed at each pixel. The orientation of the liquid crystal of each pixel may permit more or less light to pass through each pixel. The display 18 may employ any suitable technique to manipulate these electrical fields and/or the liquid crystals. For example, the display 18 may employ transverse electric field modes in which the liquid crystals are oriented by applying an in-plane electrical field to a layer of the liquid crystals. Example of such techniques include in-plane switching (IPS) and/or fringe field switching (FFS) techniques.

By controlling of the orientation of the liquid crystals, the amount of light emitted by the pixels may change. Changing the amount of light emitted by the pixels will change the colors perceived by a user of the display 18. Specifically, a group of pixels may include a red pixel, a green pixel, and a blue pixel, each having a color filter of that color. By varying the orientation of the liquid crystals of different colored pixels, a variety of different colors may be perceived by a user viewing the display. It may be noted that the individual colored pixels of a group of pixels may also be referred to as unit pixels.

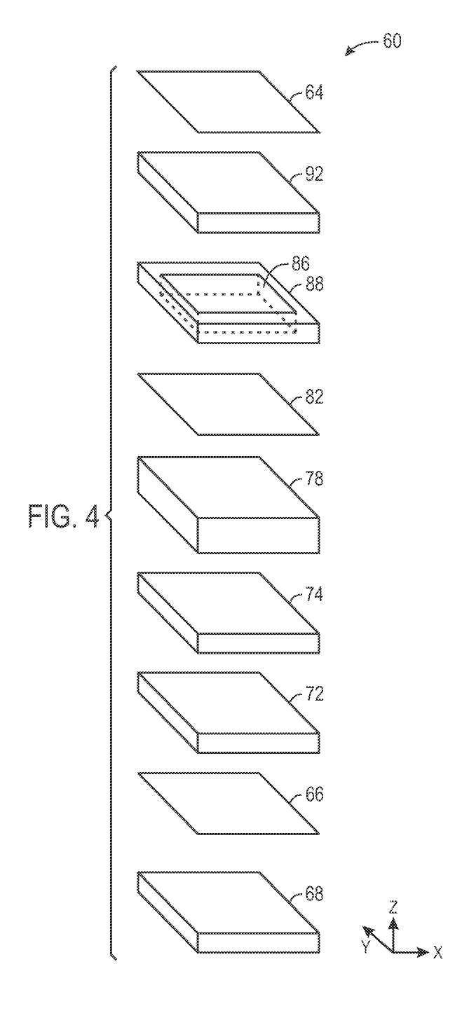

With the foregoing in mind, FIG. 4 depicts an exploded view of different layers of a pixel of the display 18. The pixel 60 includes an upper polarizing layer 64 and a lower polarizing layer 66 that polarize light emitted by a backlight assembly 68 or light-reflective surface. A lower substrate 72 is disposed above the polarizing layer 66 and is generally formed from a light-transparent material, such as glass, quartz, and/or plastic.

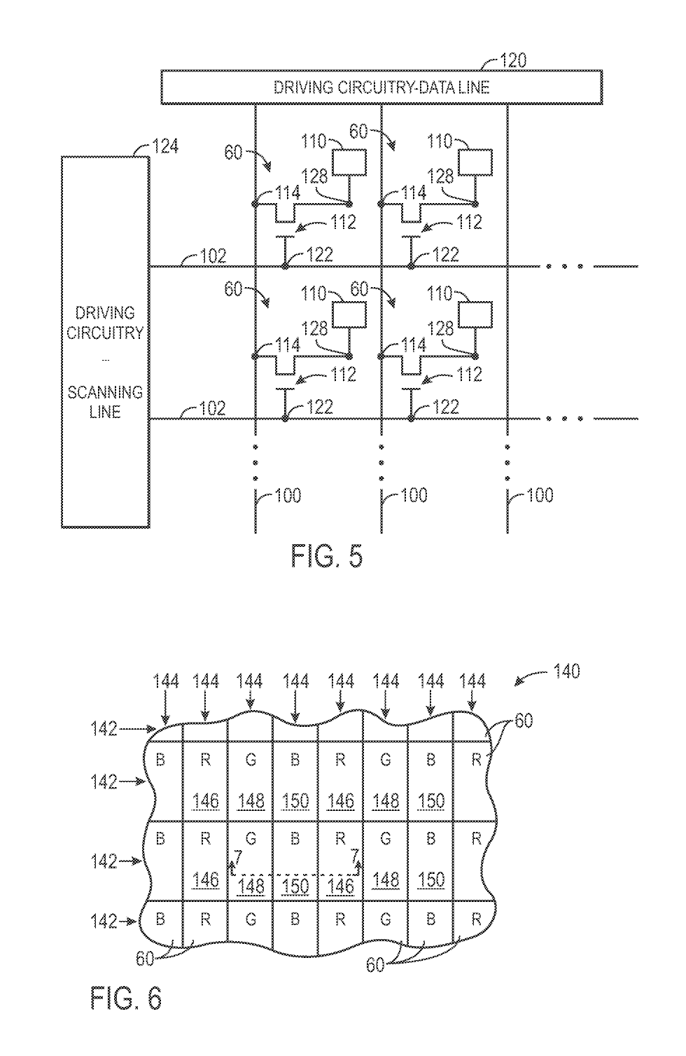

A thin film transistor (TFT) layer 74 appears above the lower substrate 72. For simplicity, the TFT layer 74 is depicted as a generalized structure in FIG. 4. In practice, the TFT layer may itself comprise various conductive, non-conductive, and semiconductive layers and structures that generally form the electrical devices and pathways that drive the operation of the pixel 60. For example, when the pixel 60 is part of an FFS LCD panel, the TFT layer 74 may include the respective data lines, scanning or gate lines, pixel electrodes, and common electrodes (as well as other conductive traces and structures) of the pixel 60. In light-transmissive portions of the pixel 60, these conductive structures may be formed using transparent conductive materials such as indium tin oxide (ITO). In addition, the TFT layer 74 may include insulating layers (such as a gate insulating film) formed from suitable transparent materials (such as silicon oxide) and semiconductive layers formed from suitable semiconductor materials (such as amorphous silicon). In general, the respective conductive structures and traces, insulating structures, and semiconductor structures may be suitably disposed to form the respective pixel and common electrodes, a TFT, and the respective data and scanning lines used to operate the pixel 60, as described in further detail below with regard to FIG. 5. The TFT layer 74 may also include an alignment layer (formed from polyimide or other suitable materials) at the interface with a liquid crystal layer 78.

The liquid crystal layer 78 includes liquid crystal particles or molecules suspended in a fluid or gel matrix. The liquid crystal particles may be oriented or aligned with respect to an electrical field generated by the TFT layer 74. The orientation of the liquid crystal particles in the liquid crystal layer 78 determines the amount of light transmission through the pixel 60. Thus, by modulation of the electrical field applied to the liquid crystal layer 78, the amount of light transmitted though the pixel 60 may be correspondingly modulated.

Disposed on the other side of the liquid crystal layer 78 from the TFT layer 74 may be one or more alignment and/or overcoating layers 82 interfacing between the liquid crystal layer 78 and an overlying color filter 86. The color filter 86 may be a red, green, or blue filter, for example. Thus, each pixel 60 corresponds to a primary color when light is transmitted from the backlight assembly 68 through the liquid crystal layer 78 and the color filter 86.

The color filter 86 may be surrounded by a light-opaque mask or matrix, represented here as a black mask 88. The black mask 88 circumscribes the light-transmissive portion of the pixel 60, delineating the pixel edges. The black mask 88 may be sized and shaped to define a light-transmissive aperture over the liquid crystal layer 78 and around the color filter 86. In addition, the black mask 88 may cover or mask portions of the pixel 60 that do not transmit light, such as the scanning line and data line driving circuitry, the TFT, and the periphery of the pixel 60. In the example of FIG. 4, an upper substrate 92 may be disposed between the black mask 88 and color filter 86 and the polarizing layer 64. The upper substrate 92 may be formed from light-transmissive glass, quartz, and/or plastic.

One example of a circuit view of pixel driving circuitry found in a display 18 appears in FIG. 5. The circuitry of FIG. 5 may be embodied, for example, in the TFT layer 74 described with respect to FIG. 4. In the example of FIG. 5, the pixels 60 may be disposed in a matrix that forms an image display region of a display 18. In this matrix, each pixel 60 may be defined by the intersection of data lines 100 and scanning or gate lines 102.

Each pixel 60 includes a pixel electrode 110 and thin film transistor (TFT) 112 for switching the pixel electrode 110. The source 114 of each TFT 112 may be electrically connected to a data line 100, extending from respective data line driving circuitry 120. Similarly, the gate 122 of each TFT 112 may be electrically connected to a scanning or gate line 102, extending from respective scanning line driving circuitry 124. In the example of FIG. 5, the pixel electrode 110 is electrically connected to a drain 128 of the respective TFT 112.

In one embodiment, the data line driving circuitry 120 sends image signals to the pixels via the respective data lines 100. Such image signals may be applied by line sequence (i.e., the data lines 100 may be sequentially activated during operation). The scanning lines 102 may apply scanning signals from the scanning line driving circuitry 124 to the gate 122 of each TFT 112 to which the respective scanning lines 102 connect. Such scanning signals may be applied by line-sequence with a predetermined timing and/or in a pulsed manner.

Each TFT 112 serves as a switching element that can be activated and deactivated (i.e., turned on and off) for a predetermined period based on the respective presence or absence of a scanning signal at the gate 122 of the TFT 112. When activated, a TFT 112 may store the image signals received via a respective data line 100 as a charge in the pixel electrode 110 with a predetermined timing.

The image signals stored at the pixel electrode 110 may be used to generate an electrical field between the respective pixel electrode 110 and a common electrode (not shown in FIG. 5). The electrical field may align liquid crystals within the liquid crystal layer 78 (FIG. 4) to modulate light transmission through the liquid crystal layer 78. In some embodiments, a storage capacitor may also be provided in parallel to the liquid crystal capacitor formed between the pixel electrode 110 and the common electrode to prevent leakage of the stored image signal at the pixel electrode 110. For example, the storage capacitor may be provided between the drain 128 of the respective TFT 112 and a separate capacitor line.

As depicted in FIG. 6, an LCD pixel array 140 may include a plurality of pixels 60 arranged in rows 142 and columns 144. In the presently illustrated embodiment, the array 140 includes alternating columns of red pixels 146, green pixels 148, and blue pixels 150. It is noted, however, that these various colored pixels may be provided in other arrangements, such as those in which the order of columns associated with respective colors is different, or in which the columns include pixels 60 of different colors. Additionally, the pixels 60 may include other colors in addition to, or in place of, those noted above.

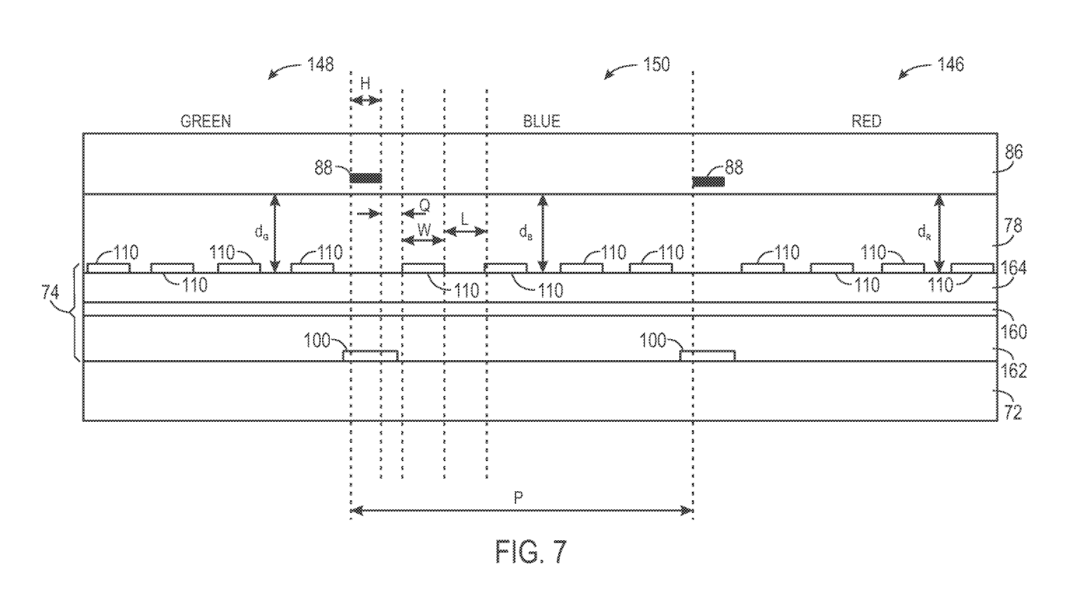

The red pixels 146, green pixels 148, and blue pixels 150 may have configurations that reduce thermal color shift over, for example, a 20° C. range of normal operating temperatures. As seen in a schematic cross-sectional view of a red pixel 146, a green pixel 148, and a blue pixel 150 shown in FIG. 7, the cell gap depths d_{R}, G, B may be selected to reduce thermal color shift, as may be certain numbers and proportions of fingers of the pixel electrodes 110. In the cross-sectional view of FIG. 7, certain components of the red pixel 146, the green pixel 148, and the blue pixel 150 are shown. Specifically, these pixels 146, 148, and 150 are disposed over the lower substrate layer 72. Data lines 100 may be formed over the lower substrate layer 72 in the TFT layer 74. The TFT layer 74 may include a common electrode 160 disposed over a dielectric layer 162, which may serve as a dielectric between data lines 100 and thin film transistors (TFTs) 112 (not seen in FIG. 7) and a corresponding common electrode 160. A passivation layer 164 may be disposed above the common electrode 160. The pixel electrodes 110 of the red pixel 146, the green pixel 148, and blue pixel 150 may be formed directly on top of the passivation layer 164.

Above the TFT layer 74 is disposed a liquid crystal layer 78. The liquid crystal layer 78 may include a fluid or gel containing liquid crystal molecules that vary in alignment responsive to an electric field. The liquid crystal material may be selected from materials having a positive or a negative dielectric anisotropy. The liquid crystal material may have birefringence characteristics. These characteristics may impact the manner in which different wavelengths of light are transmitted through the liquid crystal layer 78. In some embodiments, the optical birefringence (Δn) of the liquid crystal layer 78 may be approximately 0.105 at 589 nm, and the typical Δn of the liquid crystals can range from 0.08 to 0.12 at 589 nm. In general, the phase retardation dΔn/λ (liquid crystal birefringence (Δn) times a cell gap depth (d) divided by the wavelength of light (λ)) may be set to be from 320 nm to 350 nm for the green wavelength at 550 nm. It should be appreciated that other suitable birefringence characteristics may be employed, and that the birefringence indicated here represents only one example that may be used.

As noted above, the orientation of the liquid crystal molecules of the liquid crystal layer 78 may vary based on an electric field passing through the liquid crystal layer 78 due to a voltage difference between the fingers of the pixel electrodes 110 and the common electrode 160. The change in orientation of the liquid crystal molecules of the liquid crystal layer 78 ultimately effects the light passing through the liquid crystal layer 78 (e.g., by altering the polarization of the light) and ultimately causes the transmittance of the light to vary based on the voltage difference between the fingers of the pixel electrodes 110 and the common electrode 160. Light passing through the liquid crystal layer 78 passes through a red color filter in the color filter layer 86 of the red pixel 146, a green color filter in the color filter layer 86 of the green pixel 148, and a blue color filter in the color filter layer 86 of the blue pixel 150. By way of example, the color filters of the color filter layer 86 may permit wavelengths of light of approximately 650 nm, 550 nm, and 450 nm, respectively. It should be filters that permit other suitable wavelengths of light alternatively may be employed. A black mask 88 may be formed in the color filter layer 86 and may delineate the edges of individual pixels. For example, as shown in FIG. 7, the black mask 88 separates the righthand edge of the green pixel 148 from the lefthand edge of the blue pixel 150. Likewise, the black mask 88 separates the righthand edge of the blue pixel 150 from the lefthand edge of the red pixel 146. The distance between the edges of the black mask 88 across a pixel is referred to as the pixel pitch P. An example of the pixel pitch P of the blue pixel is shown in FIG. 7.

Thermal color shift is believed to arise when the temperature changes and the red pixel 146, green pixel 148, and/or blue pixel 150 respectively increase or decrease the transmittance of light in an unequal manner from the others. Moreover, it is believed that light phase retardation and the liquid crystal profile (first order) is the root cause of this thermal color shift. Thus, the window to thermal insensitivity (e.g., a change in transmittance of less than 1% for a 20° C. change) for phase retardation dΔn/λ (liquid crystal birefringence (Δn) times a cell gap depth (d) divided by the wavelength of light (λ)) is believed to be roughly around the range (0.725, 0.775) in CIE 1976 color space. Accordingly, it is believed that thermal color shift will be reduced or even substantially eliminated for a 20° C. change in the range of 30° C. to 50° C. by using significantly different cell gap depths (d) for the red pixels 146, green pixels 148, and blue pixels 150.

For example, when the birefringence (Δn) of the liquid crystal layer 78 is fixed at about 0.105 at 589 nm, the cell gap depths (d) that could make each color insensitive to temperature change may be d_{B}≈3.0 μm for the blue pixel 150, d_{G} approximately ≈4.0 μm for the green pixel 148, and d_{R}≈5.0 μm for the red pixel 146. Thus, by forming the TFT layer 74 and/or the color filter layer 86 such that the cell gap depths d_{B} d_{G}, d_{R} have the values indicated above, it is believed that the thermal color shift of delta u′v′ in the CIE 1976 color standard may be reduced substantially over a 20° C. temperature change (e.g., from 30° C. to 50° C.) over displays 18 without thermally compensated pixels 20. It should be understood that the variable cell gap depths (d) may be achieved using any suitable fabrication technique.

Additionally or alternatively, the red pixel 146, green pixel 148, and/or blue pixel 150 may be thermally compensated to reduce thermal color shift via certain proportions of pixel structures other than the cell gap depth (d). For example, the number of fingers of the pixel electrodes 110, the width (W) of each pixel electrode 110 finger, and/or the spacing (L) between the pixel electrode 110 fingers may be selected to reduce thermal color shift. Moreover, in certain embodiments, the number and/or proportions of the pixel electrode 110 of one color pixel (e.g., the blue pixel 150) may differ from that of another color pixel (e.g., the red pixel 146 or the green pixel 148). To provide a few brief examples, which will be discussed in greater further detail below, the blue pixel 150 may include 5 pixel electrode 110 fingers while the red pixel 146 and the green pixel 148 may include only four pixel electrode fingers. Additionally or alternatively, a black mask 88 width H may be wider or less wide at the edge of one color pixel (e.g., the blue pixel 150) than at the edge of another pixel (e.g., the red pixel 146 or the green pixel 148). Likewise, as the black mask 88 may delineate a pixel edge that is parallel to the fingers of the pixel electrode 110, varying the width H of the black mask 88 may accordingly vary the distance Q between the black mask edge and the pixel electrode 110. As will be discussed below, reducing the distance Q between the black edge and the pixel electrode 110 of the blue pixel 150 may reduce thermal color shift by the blue pixel 150. It is believed that transmittance increases along the outer edges of the blue pixel 150 in a more dramatic manner than the red pixel 146 or the green pixel 148.

The cell gap depth d_{R} of the red pixel 146, d_{G} of the green pixel 148, and d_{B} of the blue pixel 150 may be the same in some embodiments. Certain values of such a common cell gap depth may provide better thermal color shift reduction than others. For example, FIG. 8 represents a bar graph 170 illustrating different values of thermal color shift modeled for various uniform cell gap depths d_{R}, d_{G}, and d_{B} as temperature changes from 30° C. to 50° C. The thermal color shift values of FIG. 8 are provided in terms of delta u′v′ in the CIE 1976 color space. An ordinate 172 represents values of delta u′v′ from 0.00 to 0.02. An abscissa 174 represents cell gap depth d_{R}, d_{G}, and d_{B} at values of 3.0 μm, 3.2 μm, 3.4 μm, and 3.8 μm when the birefringence (ΣΔn) of the liquid crystal layer 78 is about 0.105 at 589 nm. In the example of FIG. 8, the liquid crystal has positive dielectric anisotropy at about +10.

As apparent from the bar graph 170 of FIG. 8, if a uniform cell gap depth d_{R}, d_{G}, and d_{B} is selected, a thinner cell gap is preferred. Specifically, as indicated at numeral 176, when the cell gap depth d_{R}, d_{G}, and d_{B} equals 3.0 μm, the thermal color shift has been modeled to be approximately 0.0073. By contrast, larger cell gap depths d of 3.2 μm and 3.4 μm are shown to have thermal color shifts of delta u′v′ of 0.0084 and 0.0092, respectively, as shown at numerals 178 and 180. At the point where the common cell gap depth d_{R}, d_{G}, and d_{B} is 3.8 μm, as indicated at numeral 182, the thermal color shift has been modeled to be a delta u′v′ of 0.0112, and is expected to be higher as the cell gap depth d increased. In sum, a thermal color shift of delta u′v′ of 0.0092 or lower may be achieved using a common cell gap depth d_{R}, d_{G}, and d_{B} of between about 3.0 μm and 3.4 μm or lower. The cell gap of the cell may be selected to make phase retardation dΔn/λ of the green color at room temperature to be about 330 nm to 350 nm.

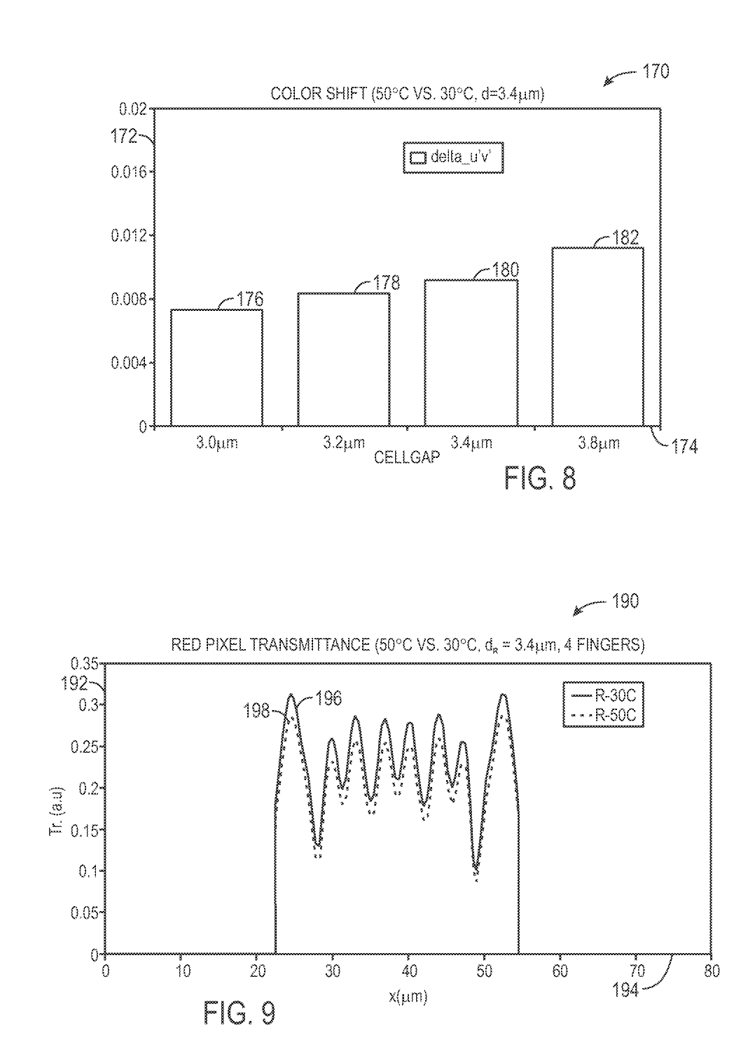

Although uniform, relatively small cell gap depths d_{R}, d_{G}, and d_{B} may reduce thermal color shift, it may also be beneficial to vary the configurations of the red pixel 146, green pixel 148, and/or blue pixel 150 relative to one another. Specifically, it is believed that the transmittance of each of these color pixels may change in different ways over a 20° C. change in temperature, and thus the configuration of pixels of certain colors may be selected to be different from pixels of other colors. Indeed, as shown by FIGS. 9-11, the red pixel 146 transmittance, green pixel 148 transmittance, and blue pixel 150 transmittance may vary in different ways with changes in temperature.

For example, as shown by a plot 190 of FIG. 9, the transmittance of a red pixel 146 may uniformly decrease between an operating temperature of 30° C. to 50° C. In the plot 190, an ordinate 192 represents transmittance in absorbance units (a.u.) from 0 to 0.35. An abscissa 194 represents a simulated distance in units of micrometers (μm) across the pitch P of a red pixel 146. In the example of the plot 190, the red pixel 146 is understood to have a pixel pitch P that extends from approximately 23 μm to 55 μm. In addition, the red pixel 146 modeled in the plot 190 has a cell gap depth d_{R} of 3.4 μm and four fingers. In the plot 190 of FIG. 9, a curve 196 represents the transmittance of the red pixel 146 modeled at a temperature of 30° C. A curve 198 represents the transmittance of the red pixel 146 modeled at 50° C. As can be seen, the transmittance of the red pixel 146 appears to decrease substantially uniformly across its entire length. The changes in transmittance near the edges of the red pixel 146 (i.e., the differences between the curve 196 and the curve 198) do not appear to be substantially different from the changes in transmittance in other locations through the red pixel 146.

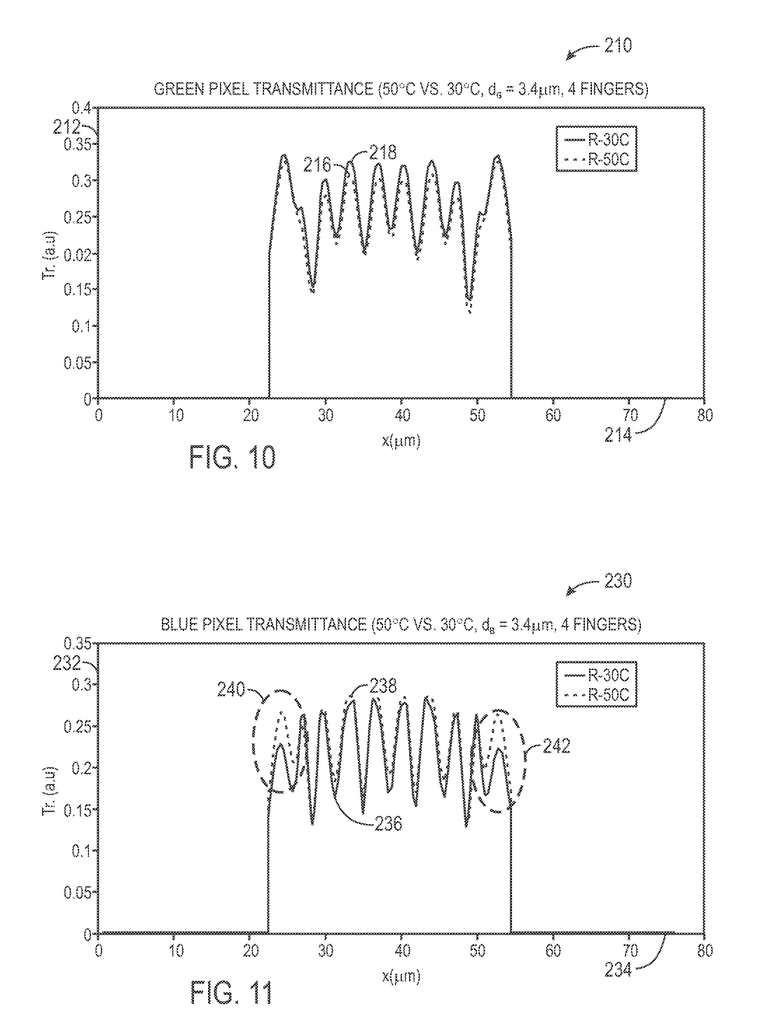

Turning to FIG. 10, a plot 210 models the transmittance of the green pixel 148 between an operating temperature of 30° C. and 50° C. In the plot 212, an ordinate represents transmittance in absorbance units (a.u.) from 0 to 0.4. An abscissa 214 represents a distance across the pitch P of the green pixel 148 in units of micrometers (μm). The pixel pitch P of the green pixel 148 modeled in the plot 210 of FIG. 10 is understood to delineate the pixel edges from approximately 23 μm to approximately 55 μm. Between the distances 23 μm and 55 μm, the green pixel 148 is understood to have 4 pixel electrode 110 fingers and have a cell gap depth d_{G} of 3.4 μm.

A curve 216 represents the transmittance of the green pixel 148 at approximately 30° C. A curve 218 represents the transmittance of the green pixel 148 at approximately 50° C. Thus, as seen in the plot 210, the transmittance of the green pixel 148 may increase slightly across approximately the middle two-thirds of the green pixel 148. The changes in transmittance near the edges of the green pixel 148 (i.e., the differences between the curve 216 and the curve 218) do not appear to be substantially different from other locations through the green pixel 148.

Finally, a plot 230 of FIG. 11 models the transmittance between an operating temperature of 30° C. and 50° C. of the blue pixel 150. Unlike the transmittances of the red pixel 146 and green pixel 148, modeled in FIGS. 9 and 10, respectively, the FIG. 11 illustrates that changes in the transmittance of the blue pixel 150 over changes in temperature are very different at the edges of the blue pixel 150 from other parts of the blue pixel 150.

In the plot 230, which models the transmittance of the blue pixel 150, an ordinate 232 represents transmittance in absorbance units (a.u.). An abscissa 234 represents a distance in units of micrometers (μm) across the pitch P of the blue pixel 150. That is, it may be understood that the black mask 88 delineates the pixel edges of the blue pixel 150 at approximately 23 μm and 55 μm. The blue pixel 150 is simulated to have a pixel electrode 110 with four fingers and a cell gap depth d_{B} of approximately 3.4 μm.

In the plot 230 of FIG. 11, a curve 236 illustrates transmittance at 30° C. and curve 238 represents transmittance at 50° C. The curves 236 and 238 appear to largely overlap in the middle three-fifths of the blue pixel 150. However, along the outer edges 240 and 242, at approximately the outer one-fifth of each side of the blue pixel 150, the transmittance can be seen to increase substantially from an operating temperature of 30° C. to 50° C. As such, the change in transmittance in the outer edges 240 and 242 of the blue pixel 150 may significantly impact the thermal color shift of the overall array of pixels. It is believed that the boundary liquid crystal (BLC) material of the liquid crystal layer 78 may be affected by over-phase retardation for blue light, resulting in a large change in transmittance of the edges of the blue pixel 150 relative to temperature.

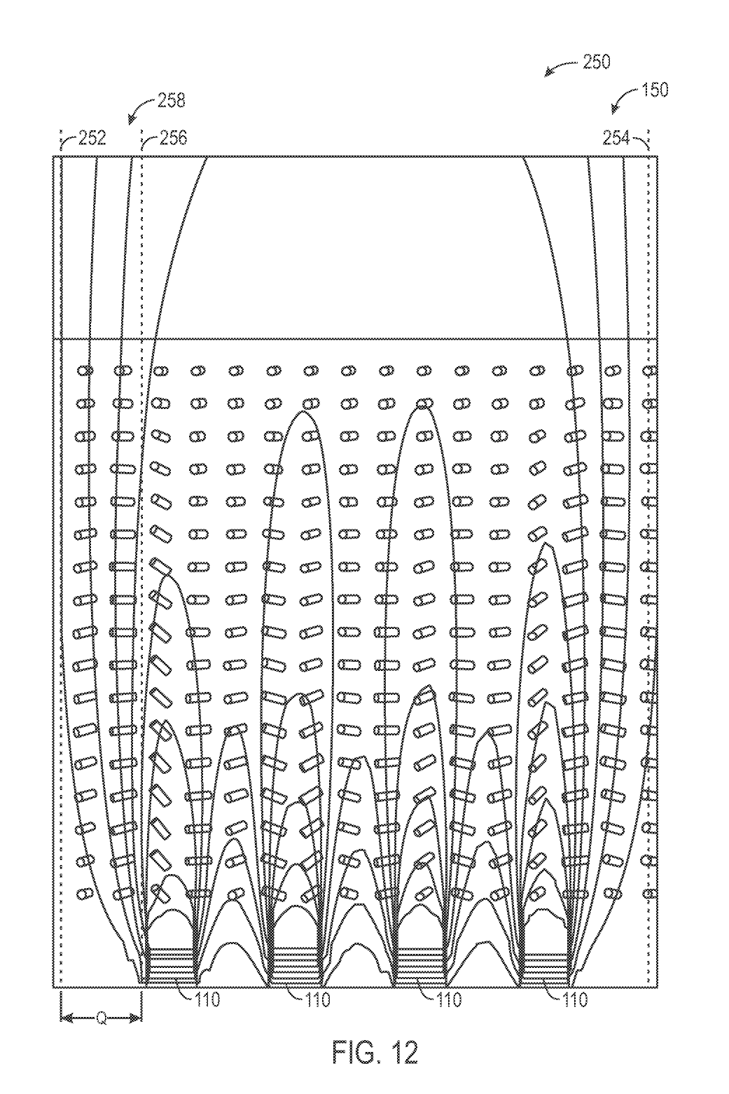

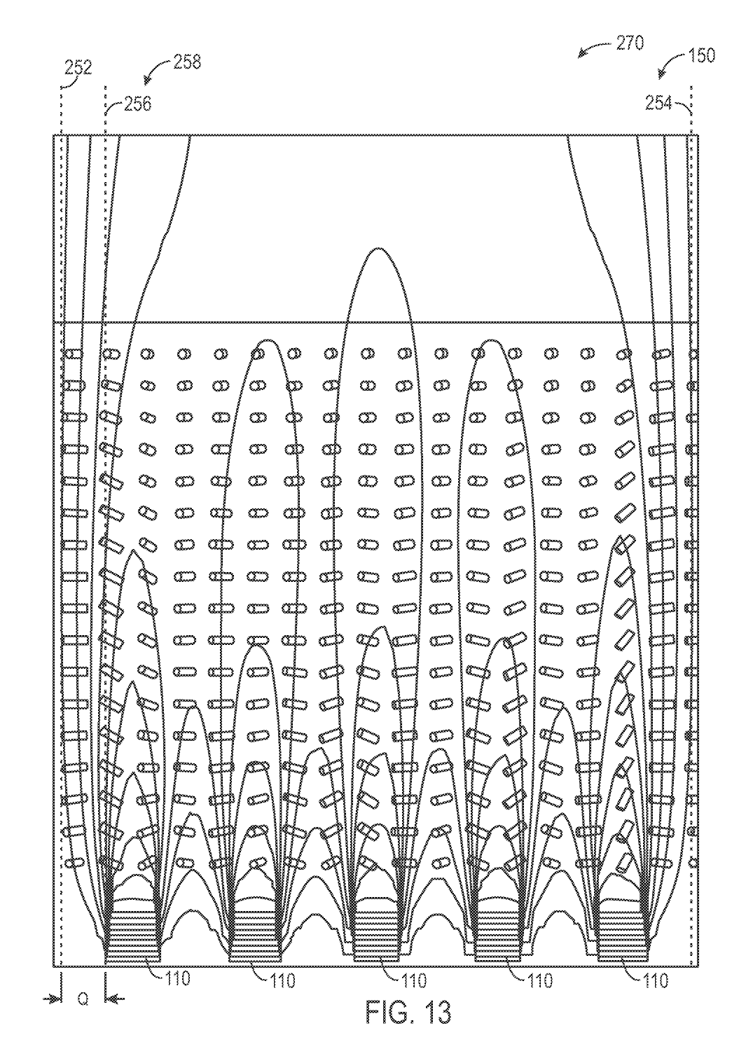

Pixel electrode 110 configurations that are different for the blue pixel 150 than for the red pixel 146 or the green pixel 148 may correct for the rapid change in transmittance at the edges 240 and 242 of the blue pixel 150. For example, as illustrated in FIGS. 12 and 13, increasing the number of pixel electrode 110 fingers from 4 to 5 in the blue pixel 150 may cause the blue pixel 150 liquid crystal layers 78 not to change in transmittance so dramatically along the outer edges 240 and 242. In particular, as shown in FIG. 12, a liquid crystal model 250 illustrates a manner in which the boundary liquid crystal (BLC) of the liquid crystal layer 78 may twist in a way that permits blue wavelengths of light more than red or green. In the liquid crystal model 250, edges of the blue pixel 150 are denoted by numerals 252 and 254, respectively. These pixel edges 252 and 254 generally representing the pixel edges delineated by the black mask 88 that would separate a blue pixel 150 from a red pixel 146 or green pixel 148. The edge of the pixel electrode 110 is represented by a numeral 256. At an outer edge 258 of the blue pixel 150, when the pixel electrode 110 includes four fingers, the electric field results in strong liquid crystal tilt. It is believed that this strong tilt produces over-phase retardation in the blue pixel 158 along this outer edge 258.

By contrast, as shown by a liquid crystal model 270 of FIG. 13, when the pixel electrode 110 includes five fingers (here, of the same width and spacing as in FIG. 12) instead of four, the strong tilt in the liquid crystal material may be largely eliminated. In the liquid crystal model 270, the rotation of the liquid crystal molecules of the liquid crystal layer 78 is modeled over the distance across the blue pixel 150. As shown in FIG. 13, the outer edges of the pixel are delineated at numerals 252 and 254 by black mask material 88. The outer edges of the blue pixel 150 at numeral 258 in FIG. 13 no longer exhibits the degree of liquid crystal tilt that appears in FIG. 12. Thus, the liquid crystal layer 78 at this outer edge 258 of the blue pixel 150 may not result in the over-phase retardation that is believed to impact the transmittance of the blue pixel 150. In addition, as may understood from the model 270 of FIG. 13, the improvement in the tilt of the liquid crystal molecules of the liquid crystal layer 78 may be due at least in part to the reduction in the distance Q between the black mask edge at numeral 252 and the pixel electrode 110. Thus, given a blue pixel 150 pixel electrode 110 configuration with multiple fingers of a particular width and spacing, more fingers rather than fewer may provide for less thermal color shift. In particular, as shown in FIG. 13, a five-finger pixel electrode 110 design may eliminate the dependency of the transmittance of the blue pixel 150 on the boundary liquid crystal (BLC) molecules of the liquid crystal layer 78. Here, the number of fingers used in each pixel is also related to the display pixel pitch. For example, as the pixel pitch is further reduced to around 20 μm, the finger number could be reduced to 3 fingers or even 2 fingers in each pixel.

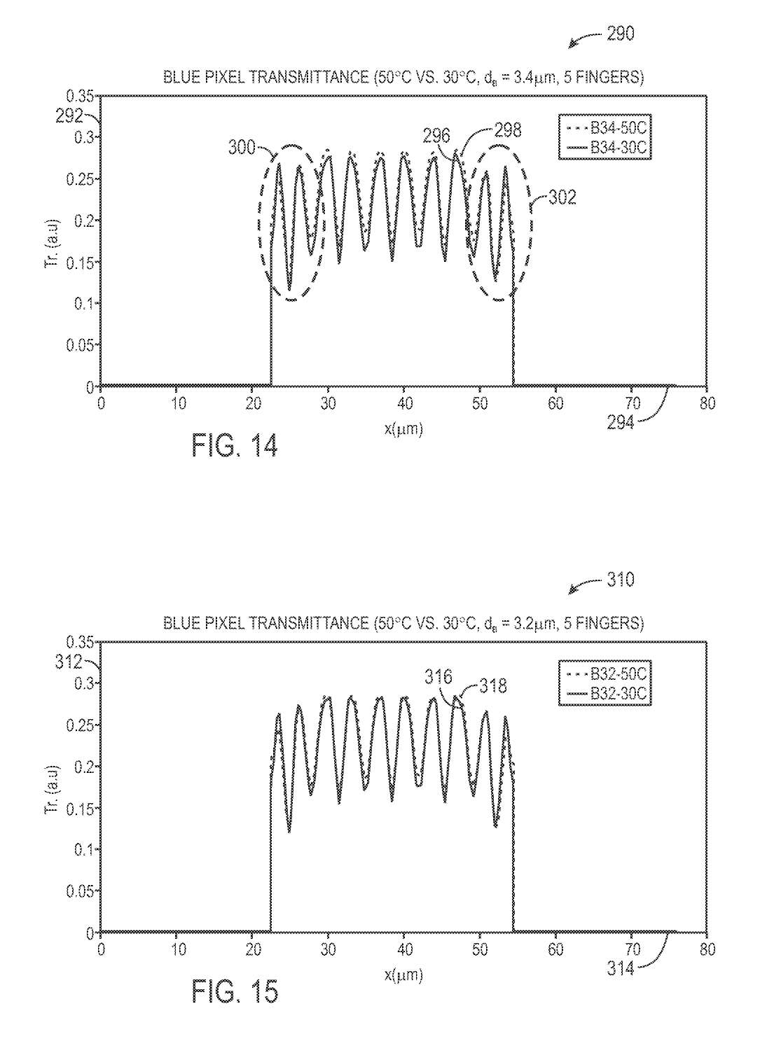

As discussed above with reference to FIGS. 7 and 8, the cell gap depths d_{R}, d_{G}, and d_{B} were demonstrated to impact the thermal color shift of the pixel array 140. Thus, even when a five-finger pixel electrode 110 design is used in the blue pixel 150, the cell gap depth d_{B} may be selected to further reduce the change in transmittance of the blue pixel 150 from 30° C. to 50° C. For example, as shown in FIGS. 14 and 15, a cell gap depth d_{B} of 3.2 μm rather than 3.4 μm may produce superior transmittance characteristics for a blue pixel 150 as temperature shifts from 30° C. to 50° C.

In particular, a plot 290 of FIG. 14 represents the transmittance of the blue pixel 150 at a cell gap depth d_{B} of 3.4 μm when the pixel electrode 110 has five fingers and the temperature changes from 30° C. to 50° C. An ordinate 292 represents transmittance in absorbance units (a.u.) from 0 to 0.35. An abscissa 294 represents a distance across the pitch of the blue pixel 150 in units of micrometers (μm). Along the abscissa 294, the outer pixel edges of the blue pixel 150 occur at approximately 23 μm and 55 μm, respectively. A curve 296 represents the transmittance of the blue pixel 150 modeled at 30° C. and a curve 298 represents the transmittance of the blue pixel 150 modeled at 50° C. Although the outer edges 300 and 302 of the blue pixel 150 have improved over a four-finger design, the transmittance does appear to vary appreciably from 30° C. to 50° C.

In contrast, a plot 310 of FIG. 15 represents the transmittance of the blue pixel 150 when the pixel electrode 110 has five fingers and the temperature changes from 30° C. to 50° C., but at a cell gap depth d_{B} of 3.2 μm rather than 3.4 μm. As can be seen in the plot 310, in which a curve 316 represents the transmittance of the blue pixel 150 at 30° C. and a curve 318 represents the transmittance of the blue pixel 150 at 50° C., the transmittance of the blue pixel 150 changes very little when the cell gap depth d_{B} is approximately equal to 3.2 μm. Thus, it is believed that a pixel configuration in which the cell gap depth d_{B} of the blue pixel 150 is lower than the cell gap depths d_{R} or d_{G} of the red pixel 146 and green pixel 148, respectively, may reduce the thermal color shift of the pixel array 140.

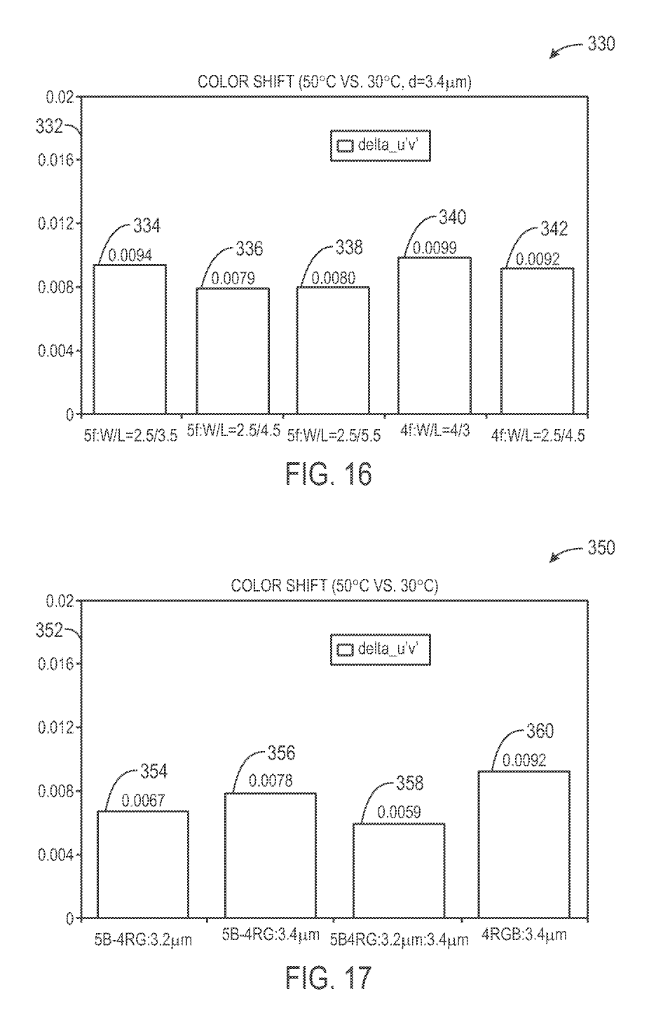

The relative proportions of the pixel electrodes 110 of the red pixel 146, green pixel 148, and/or blue pixel 150 may also impact the degree of thermal color shift that the display 18 may undergo when the temperature increases by 20° C. over a starting operating temperature. For example, a bar graph 330 of FIG. 16 models thermal color shift of the delta u′v′ in the CIE 1976 color space of configurations with varying pixel electrode 110 proportions. The bar graph 330 of FIG. 16 illustrates the impact of varying pixel electrode 110 proportions on the thermal color shift of the pixel array 140 when temperature changes from 30° C. to 50° C. All of the configurations of the bar graph 330 model a uniform cell gap depth d_{R}, d_{G}, and d_{B} of 3.4 μm. In the bar graph 330, the ordinate 332 represents thermal color shift as delta u′v′ in the CIE 1976 color space as temperature changes from 30° C. to 50° C. Numerals 334, 336, 338, 340, and 342 represent various values of thermal color shift of delta u′v′ for different pixel electrode 110 numbers and with-spacing proportions. As modeled in the bar graph 330 of FIG. 16, pixel electrode 110 width (W) remained within a range of approximately 2 μm to 5 μm, width (W) to spacing (L)_ratios (W:L) remained within a range of approximately 2:5 to 2:1, the distance Q remained less than approximately 5 μm, and the black mask 88 width H remained less than approximately 8 μm.

When all of the red pixel 146, green pixel 148, and blue pixel 150 were modeled in FIG. 16 to have pixel electrodes 110 of five fingers with a width (W) to spacing (L) ratio of 2.5:3.5, the thermal color shift was modeled to be approximately 0.0094. As indicated by the numeral 336, the thermal color shift dropped to a delta u′v′ of 0.0079 when the pixel electrode 110 width (W) to spacing (L) ratio was changed to 2.5:4.5. The thermal color shift changed little, increasing only to 0.0080 when the pixel electrode 110 width (W) to spacing (L) ratio was decreased to 2.5:5.5, as indicated at numeral 338. As indicated at numerals 340 and 342, the thermal color shift is somewhat higher when the pixel electrode 110 includes only four fingers. As shown at numeral 340, when the pixel electrode 110 has four fingers and has a pixel electrode 110 width (W) to spacing (L) ratio of 4:3, the thermal color shift is modeled to be approximately delta u′v′ of 0.0099. When the pixel electrode 110 width (W) to spacing (L) ratio was changed to 2.5:4.5, the thermal color shift declined slightly to delta u′v′ of 0.0092, as indicated at numeral 342. Thus, from the bar graph 330 of FIG. 16, it may be appreciated that if the red pixel 146, the green pixel 148, and the blue pixel 150 all have pixel electrodes 110 of the same number of fingers and the same pixel electrode 110 width (W) to spacing (L) ratios, five fingers rather than four and a width (W) to spacing (L) ratio of between approximately 2.5:5.5 to 2.5:4.5 may result in a lower thermal color shift.

The red pixel 146, the green pixel 148, and the blue pixel 150 may not necessarily have pixel electrodes 110 of the same number of fingers and the same pixel electrode 110 width (W) to spacing (L) ratios. Indeed, the red pixel 146, the green pixel 148, and the blue pixel 150 may respectively employ different numbers of pixel electrode 110 fingers, different pixel electrode 110 finger proportions, different cell gap depth d, and/or different black mask 88 widths (H) to further reduce the thermal color shift of the pixel array 140 over 30° C. to 50° C. For example, a bar graph 350 of FIG. 17 represents thermal color shift of the display 18 modeled as occurring when the blue pixel 150 has a different configuration from the red pixel 146 or the green pixel 148. An ordinate 352 represents thermal color shift as delta u′v′ in the CIE 1976 color space from 30° C. to 50° C. Numerals 354, 356, 358, and 360 generally indicate thermal color shift values of delta u′v′ associated with various configurations of the red pixel 146, green pixel 148, and blue pixel 150. As indicated at numeral 354, when the blue pixel 150 is modeled to have five pixel electrode 110 fingers, the red pixel 146 and green pixel 148 are modeled to have four pixel electrode fingers 110, and all three pixels 146, 148, and 150 have cell gap depths of 3.2 μm, the thermal color shift is modeled to be a delta u′v′ of 0.0067. Using the same number of pixel electrode 110 fingers as modeled at numeral 354 (e.g., five for the blue pixel 150 and four for the red pixel 146 and green pixel 148), but increasing all of the cell gap depths d_{R}, d_{G}, and d_{B} to 3.4 μm, a thermal color shift of delta u′v′ of 0.0078 was modeled to result at numeral 356.

As illustrated at numeral 358, the thermal color shift was shown to be smaller when the blue pixel 150 had a pixel electrode 110 with five fingers and a cell gap depth d_{B} of 3.2 μm, while the red pixel 146 and the green pixel 148 had pixel electrodes 110 of four fingers and respective cell gap depths d_{R} and d_{G} of 3.4 μm. When the red pixel 146, green pixel 148, and blue pixel 150 all employed pixel electrodes 110 having four fingers and uniform cell gap depths d_{R}, d_{G}, and d_{B} of 3.4 μm, the thermal color shift was modeled to be a delta u′v′ of 0.0092, as shown at numeral 360.

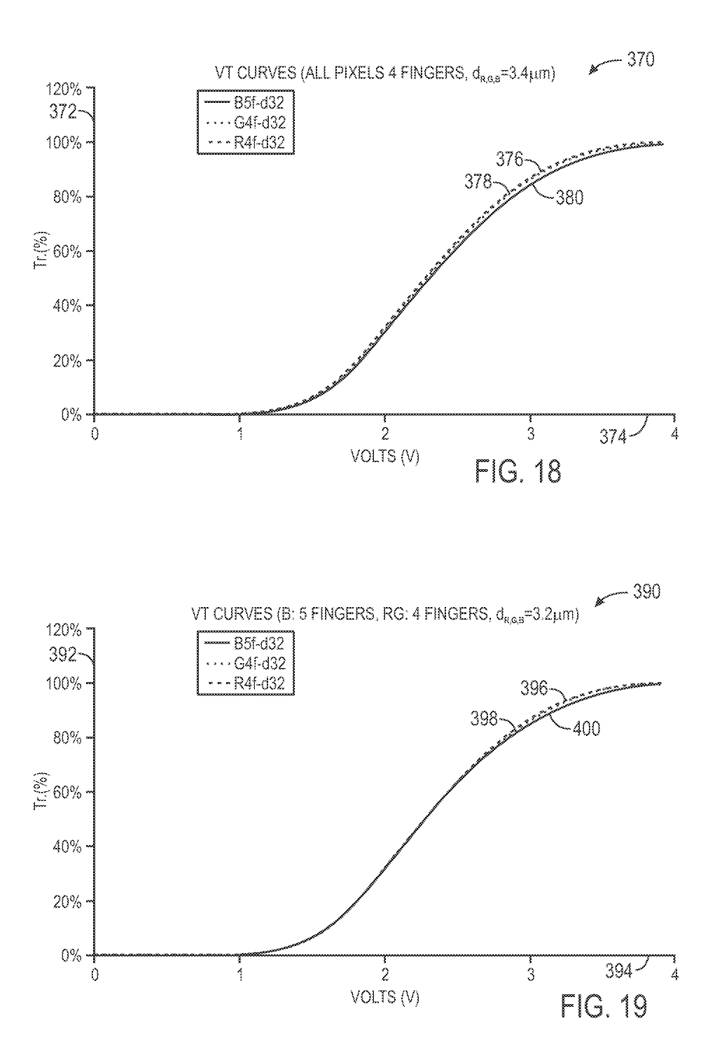

Voltage-transmittance (VT) curves are shown in FIGS. 18-20 for certain of the configurations noted above with reference to FIG. 17. In particular, FIG. 18 represents a voltage-transmittance (VT) curve 370 modeled to occur when the red pixel 146, the green pixel 148, and the blue pixel 150 all employ pixel electrodes 110 having four fingers and cell gap depths d_{R}, d_{G}, and d_{B} of 3.4 μm. The VT curve 370 of FIG. 18 includes an ordinate 372 that represents the percentage of total pixel transmittance. An abscissa 374 represents an amount of voltage applied to the pixel electrodes 110 of the pixels 146, 148, and 150 in units of volts (V). A curve 376 represents the transmittance of the red pixel 146 relative to the applied voltage, a curve 378 represents the transmittance of the green pixel 148 relative to the applied voltage, and a curve 380 represents the transmittance of the blue pixel 150 relative to the applied voltage. It may be noted that the transmittance of the red pixel 146 (curve 376) and the green pixel 148 (curve 378) appears to increase more quickly than that of the blue pixel 150 (curve 380).

FIG. 19 represents a voltage-transmittance (VT) curve 390 when the red pixel 146 and the green pixel 148 employ pixel electrodes 110 having four fingers and the blue pixel 150 employs pixel electrodes 110 having 5 fingers. The red pixel 146, the green pixel 148, and the are all modeled to include respective cell gap depths d_{R}, d_{G}, and d_{B} of 3.2 μm. The VT curve 390 of FIG. 19 includes an ordinate 392 that represents the percentage of total pixel transmittance. An abscissa 394 represents an amount of voltage applied to the pixel electrodes 110 of the pixels 146, 148, and 150 in units of volts (V). A curve 396 represents the transmittance of the red pixel 146, a curve 398 represents the transmittance of the green pixel 148, and a curve 400 represents the transmittance of the blue pixel 150 relative to the amount of voltage applied to the pixel electrodes 110. Like the VT curve 370 of FIG. 18, the VT curve 390 of FIG. 19 illustrates that the transmittance of the red pixel 146 (curve 396) and the green pixel 148 (curve 398) appears to increase more quickly than that of the blue pixel 150 (curve 400). However, the transmittance of the blue pixel 150 (curve 400) appears to more closely approach that of the red pixel 146 (curve 396) and the green pixel 148 (curve 398) in the configuration modeled in FIG. 19 rather than the configuration modeled in FIG. 18.

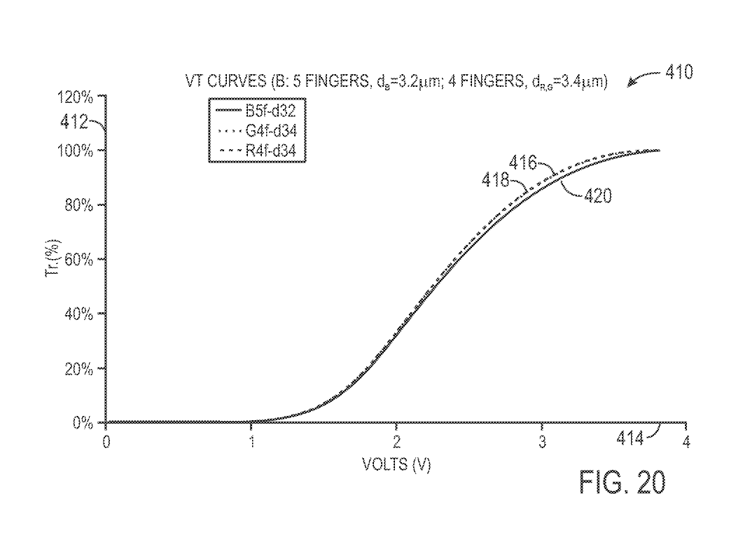

FIG. 20 represents a voltage-transmittance (VT) curve 410 when the red pixel 146 and the green pixel 148 employ pixel electrodes 110 having four fingers and the blue pixel 150 employs pixel electrodes 110 having 5 fingers. In addition, the red pixel 146 and the green pixel 148 are modeled to include respective cell gap depths d_{R} and d_{G} 3.4 μm. The blue pixel 150 is modeled to include a cell gap depth d_{B} of 3.2 μm. The VT curve 410 of FIG. 19 includes an ordinate 412 that represents the percentage of total pixel transmittance. An abscissa 414 represents an amount of voltage applied to the pixel electrodes 110 of the pixels 146, 148, and 150 in units of volts (V). A curve 416 represents the transmittance of the red pixel 146, a curve 418 represents the transmittance of the green pixel 148, and a curve 420 represents the transmittance of the blue pixel 150 relative to the amount of voltage applied to the pixel electrodes 110. The VT curve 410 of FIG. 20 illustrates that the transmittances of the red pixel 146 (curve 396) and the green pixel 148 (curve 398) appear to increase more quickly than that of the blue pixel 150 (curve 400). This effect is slightly greater than, but remains comparable to, that exhibited by the configuration modeled in FIG. 18. In other words, the configuration modeled in FIG. 20 will not result in significant disadvantages in VT curve behavior relative to the configuration of FIG. 18.

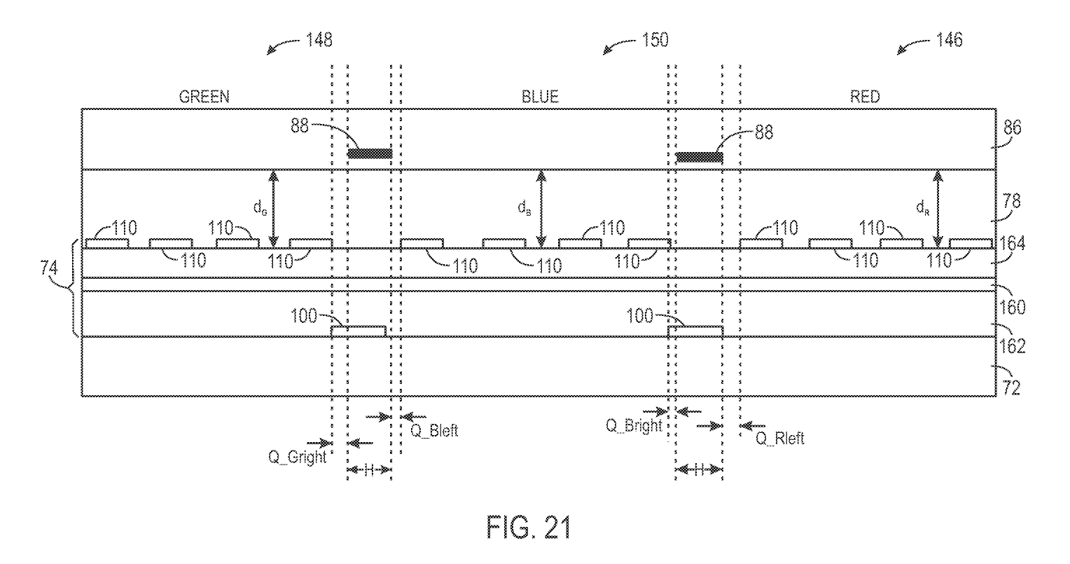

From the disclosure above, it may be appreciated that thermally compensated pixels 20 for an electronic display 18 may be obtained in a variety of ways. For example, FIG. 21 illustrates another cross-sectional view of the pixel array 140 in which the outer edges of the blue pixel 150 are smaller than the outer edges of the red pixel 146 or the green pixel 148. Like the cross-sectional view of FIG. 7, FIG. 21 illustrates various components that may be present among the red pixels 146, green pixels 148, and blue pixels 150. Elements discussed above with reference to FIG. 7 should be understood to be substantially similar and thus are not discussed further. In the example of FIG. 21, the red pixel 146, green pixel 148, and blue pixel 150 all include the same number of pixel electrode 110 fingers (four), but it may be appreciated that any suitable number of pixel electrode 110 fingers may be used as described above.

In the example of FIG. 21, the distance Q_Gright between the righthand edge of the green pixel 148 and the black mask 88 may be larger than the distance Q_Bleft between the lefthand edge of the blue pixel 150 and the black mask 88. Likewise, the distance Q_Bright between the righthand edge of the blue pixel 150 and the black mask 88 may be smaller than the distance Q_Rleft between the lefthand edge of the red pixel 146 and the black mask 88. The effect of the smaller distances Q_Bleft and Q_Bright may prevent the change in transmission of blue light through the outer edges of the blue pixel 150 as temperature changes from 30° C. to 50° C., as generally described above with reference to FIG. 11. The size of the distances Q_Bleft and Q_Bright may result, for example, from shifting the black mask material more closely to the blue pixel 150 than the red pixel 146 and green pixel 148 or by changing the width H of the black mask 88 that borders the blue pixel 150 to encroach more on the blue pixel 150. In addition, in FIG. 21, the red pixel 146, green pixel 148, and blue pixel 150 may have different cellgaps (e.g., d_{R}˜3.4 μm, d_{G}˜3.4 μm, and d_{B}˜3.2 μm or even 3.1 μm).

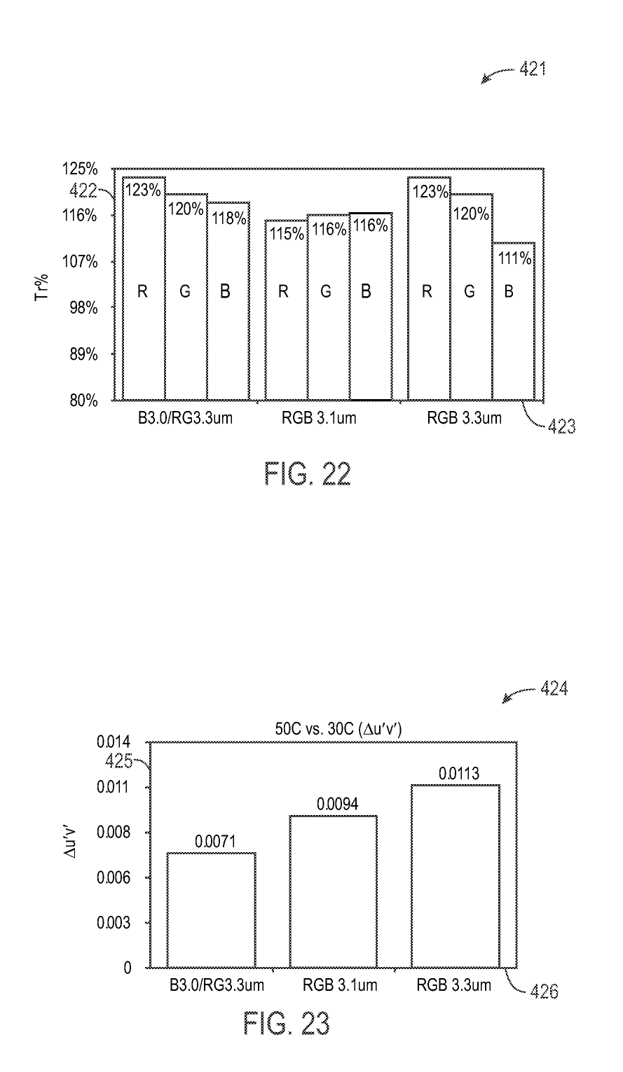

In addition, liquid crystal material with a negative dielectric anisotropy may also be used. FIG. 22 illustrates a bar plot 421 of the display transmittance at different cellgaps in red, green and blue pixels when using a negative dielectric anisotropy liquid crystal material. In this example, the dielectric anisotropy is about −3.9. An ordinate 422 represents the transmittance in absorbance units (a.u.). The transmittance is also shown in a relative scale in percentage in each bar. An abscissa 423 illustrates three different pixel configurations with different cell gap depths (d)—namely, a first pixel configuration in which d_{B}=3.0 μm and d_{R,G}=3.3 μm; a second pixel configuration in which d_{R,G,B}=3.1 μm; and a third pixel configuration in which d_{R,G,B}=3.3 μm. As seen FIG. 22, at a uniform 3.3 μm cell gap, red color has a transmittance (a.u.) as 123%, green color is 120%, and blue color is 111%. At a uniform 3.1 μm cell gap, the value changes to 115%, 116%, and 116% for red, green, and blue respectively. When red and green use the 3.3 μm cell gap, the blue utilizes the 3.0 μm cell gap, the transmittance changes to 123%, 120%, and 118% for red, green, and blue respectively.

FIG. 23 is a plot 424 showing the color shift at a 20° C. temperature change for the same pixel configurations as discussed in the example of FIG. 22. An ordinate 425 of the plot 424 represents delta u′v′ in the CIE 1976 color space. An abscissa 426 represents the three different pixel configurations with different cell gap depths (d) mentioned above—namely, the first pixel configuration in which d_{B}=3.0 μm and d_{R,G}=3.3 μm; the second pixel configuration in which d_{R,G,B}=3.1 μm; and the third pixel configuration in which d_{R,G,B}=3.3 μm. As seen in the plot 424 of FIG. 23, for a negative liquid crystal material, the uniform cell gap at 3.3 μm results in a delta u′v′ value of 0.0113, and it reduces to 0.0094 when cell gap decreases to 3.1 μm uniformly. When red and green use keep the 3.3 μm cell gap, but blue adopts the 3.0 um cell gap, the delta u′v′ value is further reduced to 0.071. Here at 3.3 μm cell gap, the green pixel phase retardation is about 340 nm.

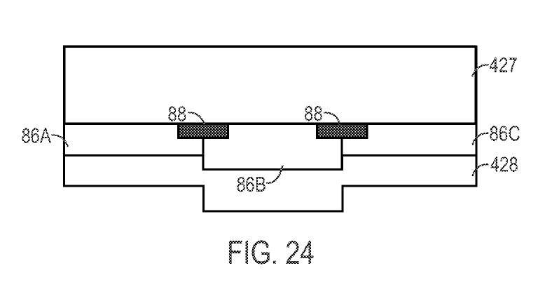

FIG. 24 illustrates one example of how different cell gaps may be achieved in the pixels. First, a black mask layer 88 may be patterned on a substrate 427, then color filter resins of red (86A), green (86C), and blue (86B) are formed on the substrate 427. Here, the thickness of the blue color filter resin 86B is processed to have a thicker resin layer than the red and green, (e.g., approximately 0.8 μm greater). Further, an overcoating layer 428 is coated on the color filter resins 86A, 86B, and 86C. The non-uniform color filter resin surface profile is then transferred to the overcoating layer 428 to cause a reduced cell gap (e.g., by approximately 0.3 μm) for the liquid crystal layer that will be located in the blue color filter 86B region. Additionally or alternatively, the different cell gaps in red, blue, and green can also be achieved by using different masks for these three colors, or a half-tone mask for all the colors.

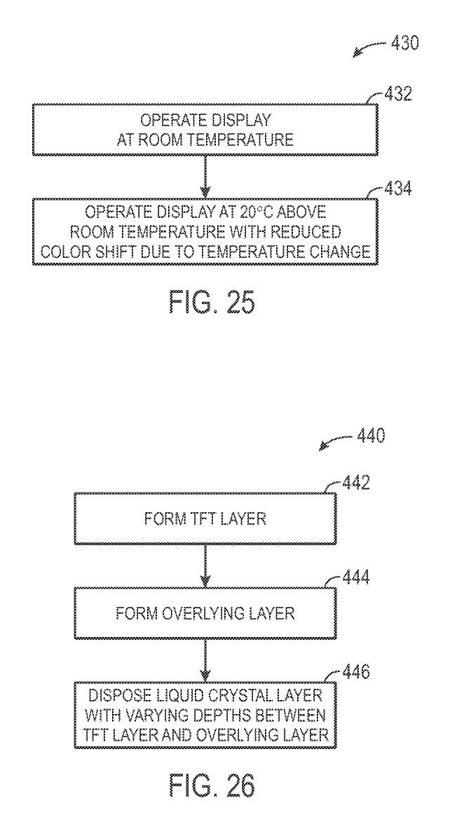

An electronic display 18 employing such thermally compensated pixels 20 according to the various configurations discussed above may have a reduced thermal color shift at different temperatures. A flowchart 430 of FIG. 25 represents one manner of operating such an electronic display 18. The flowchart 430 may begin when the electronic display 18 is operated substantially at room temperature for a standard starting operating temperature (e.g., between approximately 20° C. to 30° C.) (block 432). That is, the thermally compensated pixels 20 may be programmed with pixel data at the starting operating temperature. Thereafter, the temperature may increase at certain locations on the display 18 due to changes in the environment in which the electronic display 18 is being used, or due to increased heat due to internal components of the electronic device 10 in which the display 18 is installed. The display 18 may continue to be operated despite and increase in temperature of approximately 20° C. (block 434). For example, the thermally compensated pixels 20 may be programmed with pixel data. Despite differences in temperature, the pixel array 140 of the display 18 may exhibit a thermal color shift of delta u′v′ in the CIE 1976 color space of less than approximately 0.0092 due to the configuration of the red pixels 146, green pixels 148, and blue pixels 150 of the display 18. Such a configuration may be selected, for example, based on the disclosure set forth above.

The electronic display 18 may be manufactured using any suitable techniques. For example, a flowchart 440 of FIG. 26 describes one embodiment of a method for manufacturing a display 18 with thermally compensated pixels 20. That is, the thin film transistor (TFT) layer 74 may be formed on a lower substrate 72 (block 442). As should be understood, forming the TFT layer 74 may involve patterning different numbers of pixel electrode 110 fingers on the blue pixel 150 than the red pixels 146 or green pixels 148. The proportions of the pixel electrode 110 fingers may also vary. An overlying layer, which may be a color filter layer 86 with black mask 88 materials, may be formed on an upper substrate (block 444). This overlying layer may be placed over the TFT layer 74 with an intervening liquid crystal layer 78. The liquid crystal layer 78 may have cell gap depths d_{R}, d_{G}, and d_{B} respectively associated with the red pixel 146, green pixel 148, and blue pixel 150 that vary or remain the same (block 446). It should be appreciated that the liquid crystal layer 78 may achieve such varying cell gap depths d_{R}, d_{G}, and d_{B} according to any suitable technique, including forming the TFT layer 74 and/or the overlying layer (e.g., the color filter layer 86) to be varying heights at the various pixel colors.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

What is claimed is:

1. An electronic display comprising:
a first plurality of pixels of a first color, wherein each of the first plurality of pixels comprises:
a first pixel electrode having a first number of pixel electrode fingers of a first width and first spacing apart;
a first liquid crystal cell gap of a first depth; and
a first black mask delineating a first pixel edge located a first edge distance from the first pixel electrode; and
a second plurality of pixels of a second color, wherein each of the second plurality of pixels comprises:
a second pixel electrode having a second number of pixel electrode fingers of a second width and spacing apart;
a second liquid crystal cell gap of a second depth; and
a second black mask delineating a second pixel edge located a second edge distance from the second pixel electrode;
wherein:
the first number of pixel electrode fingers is different from the second number of pixel electrode fingers;
the first width is different from the second width;
the first spacing is different from the second spacing;
the first depth is different from the second depth; or
the first edge distance is different from the second edge distance; or
any combination thereof; and
wherein the first number of pixel electrode fingers, the second number of pixel electrode fingers, the first width, the second width, the first spacing, the second spacing, the first depth, the second depth, the first edge distance, and the second edge distance are configured to cause the electronic display to exhibit a color shift of less than delta u′v′ of about 0.0092 in the CIE 1976 color space from a starting white point when the temperature of the electronic display changes from approximately 30 degrees Celsius to approximately 50 degrees Celsius.

2. The electronic display of claim 1, wherein the first color comprises light peaking around approximately 450 nm and the second color comprises light peaking around approximately 550 nm or 650 nm.

3. The electronic display of claim 1, wherein the second color comprises a green color and the second depth is configured to provide the green color to have a phase retardation dΔn/λ at room temperature that ranges from 320 nm to 350 nm, and wherein the first color comprises a blue color and the first depth is smaller than the second depth by an amount greater than 0.1 μm.

4. The electronic display of claim 1, wherein the first number of pixel electrode fingers is at least one more than the second number of pixel electrode fingers.

5. The electronic display of claim 1, wherein the first edge distance is smaller than the second edge distance.

6. The electronic display of claim 1, wherein the first width and the first spacing relate to one another at a ratio of between about 2.5:5.5 and 2.5:4.5 and the second width and the second spacing relate to one another at a ratio of between about 2.5:4.5 and 3:4.

7. The electronic display of claim 1, wherein the first liquid crystal cell gap and the second liquid crystal cell gap comprise a liquid crystal material having a dielectric anisotropy of a negative value.

8. The electronic display of claim 1, wherein the first liquid crystal cell gap and the second liquid crystal cell gap comprise a liquid crystal material having a dielectric anisotropy of a positive value.

9. An electronic device comprising:
data processing circuitry configured to generate image data signals; and
an electronic display configured to display the image data signals on an array of pixels, each pixel of the array of pixels comprising a pixel electrode with a number of fingers, the fingers having widths and spacings sufficient to cause the image data signals to be displayed on the electronic display with a color shift of delta u′v′ of less than 0.0092 in the CIE 1976 color space when temperature increases by 20 degrees Celsius from room temperature.

10. The electronic device of claim 9, wherein all the pixels of the array of pixels comprise pixel electrodes having the same respective number of fingers and the same finger widths and spacings.

11. The electronic device of claim 10, wherein all the pixels of the array of pixels comprise pixel electrodes having fingers with finger widths and spacings that relate to one another at a ratio of between about 2.5:5.5 and 2.5:4.5.

12. The electronic device of claim 9, wherein pixels of a first plurality of pixels of the array of pixels comprise pixel electrodes with a different number of fingers with different finger widths and spacings as compared to pixel electrodes of pixels of a second plurality of pixels of the array of pixels.

13. The electronic device of claim 12, wherein the pixel electrodes of the pixels of the first plurality of pixels comprise fingers having finger widths and spacings that relate to one another at a ratio of between about 2.5:5.5 and 2.5:4.5, and wherein the pixel electrodes of the pixels of the second plurality of pixels comprise fingers numbering at least one less than those of the first plurality of pixels, the fingers of the second plurality of pixels having finger widths and spacings that relate to one another at a ratio of between about 2.5:4.5 and 3:4.

14. The electronic device of claim 13, wherein the pixels of the first plurality of pixels comprise blue pixels and the pixels of the second plurality of pixels comprise red pixels or green pixels or both red pixels and green pixels.

15. A method of manufacturing an electronic display comprising:
forming a thin film transistor layer on a lower substrate, wherein the thin film transistor layer comprises a common electrode and three pixel electrodes that correspond to three pixels of different color;
forming a black matrix layer on the upper substrate;
forming three patterned color resins on the upper substrate, wherein the three patterned color resins respectively correspond to three pixels of different colors on the lower substrate; and
forming an overcoating layer on the upper substrate; and
disposing a liquid crystal layer between the thin film transistor layer and the overcoating layer, wherein a cell gap depth of the liquid crystal layer between the thin film transistor layer and the overcoating layer at a first of the three pixels is at least 0.1 μm less than a cell gap depth of the liquid crystal layer at a second and a third of the three pixels, wherein the cell gap depths of the liquid crystal layer are sufficient to cause the liquid crystal layer to cause light transmittance to change so little over a 20 degree Celsius range of normal operating temperatures as to permit a color shift of delta u′v′ of less than approximately 0.0092 in the CIE 1976 color space.

16. The method of claim 15, wherein the first of the three pixels is a substantially blue pixel, the second of the three pixels is a substantially green pixel, and the third of three pixels is a substantially red pixel.

17. The method of claim 16, wherein liquid crystal layer is disposed such that the liquid crystal layer at the first of the three pixels has a cell gap depth of approximately 3.0 μm, the liquid layer at the second of the three pixels has a cell gap depth of approximately 4.0 μm, and the liquid crystal layer at the third of the three pixels has a cell gap depth of approximately 5.0 μm.

18. The method of claim 16, wherein the liquid crystal layer at the second of the three pixels has a cell gap depth that makes a phase retardation dΔn/λ at room temperature that ranges from 320 nm to 350 nm, the liquid crystal layer at the third of the three pixels has a cell gap depth equal to or greater than the cell gap depth at the second of the three pixels, and the liquid crystal layer at the first of the three pixels has a cell gap depth smaller than that of the second of the three pixels by an amount ranging from 0.1 um to 0.4 um.

19. An electronic display comprising:
a substantially blue pixel comprising:
a common electrode;
a pixel electrode having a plurality of fingers;
a liquid crystal layer configured to allow varying amounts of light to pass due depending an electric field caused by a voltage difference between the common electrode and the pixel electrode; and
a black mask delineating an edge of the substantially blue pixel, wherein the edge of the substantially blue pixel is substantially parallel to an outer one of the plurality of fingers of the pixel electrode, wherein a distance between the edge of the substantially blue pixel and the pixel electrode is such that approximately an outer one-fifth of the liquid crystal layer of the pixel parallel to the edge of the substantially blue pixel and the pixel electrode has a transmittance that does not substantially increase between when the electronic display is operating at a temperature of 30 degrees Celsius as when the electronic display is operating at a temperature of 50 degrees Celsius.

20. The electronic display of claim 19, wherein the plurality of fingers of the pixel electrode comprises a number of fingers of equal width and of equal spacing such that the distance between the edge of the substantially blue pixel and the pixel electrode is such that approximately the outer one-fifth of the liquid crystal layer of the pixel parallel to the edge of the substantially blue pixel and the pixel electrode has substantially the same transmittance at 30 degrees Celsius as 50 degrees Celsius.

21. The electronic display of claim 19, comprising a substantially red or substantially green pixel parallel to the substantially blue pixel, wherein the substantially red or substantially green pixel comprises another pixel electrode, wherein the black mask separates the substantially blue pixel from the substantially red or substantially green pixel and delineates an edge of the substantially red or substantially green pixel that is parallel to the other pixel electrode, and wherein the distance between the edge of the substantially blue pixel and the pixel electrode is smaller than a distance between the edge of the substantially red or substantially green pixel and the other pixel electrode.

22. A method comprising:
programming a first pixel of a first color at about room temperature with first image data, wherein the first pixel comprises:
a first pixel electrode having a first number of pixel electrode fingers of a first width and first spacing apart;
a first liquid crystal cell gap of a first depth; and
a first black mask a first horizontal distance from the first pixel electrode;
programming a second pixel of a second color at about room temperature with second image data, wherein the second pixel comprises:
a second pixel electrode having a second number of pixel electrode fingers of a second width and spacing apart;
a second liquid crystal cell gap of a second depth; and
a second black mask a second horizontal distance from the second pixel electrode;
programming the first pixel of the first color at about 20 degrees Celsius higher than room temperature with the first image data; and
programming the second pixel of the second color at about 20 degrees Celsius higher than room temperature with the second image data;
wherein:
the first number of pixel electrode fingers is different from the second number of pixel electrode fingers;
the first width is different from the second width;
the first spacing is different from the second spacing;
the first depth is different from the second depth; or
the first horizontal distance is different from the second horizontal distance; or
any combination thereof; and
wherein a color shift of the first pixel and second pixel between when the first pixel and the second pixel are programmed at about room temperature and when the first pixel and the second pixel are programmed at about 20 degrees higher than room temperature is less than delta u′v′ of about 0.0092 in the CIE 1976 color space.
